(19) United States
(12) Patent Application Publication
(10) Pub. No.: US 2026/0293224 A1
(43) Pub. Date: Sep. 24, 2026

(54) FABRICATION PROCESS METHOD FOR INCREASING AN OXIDE THICKNESS AT TRENCH BOTTOM AND A TRENCH GATE METAL-OXIDE-SEMICONDUCTOR FIELD-EFFECT TRANSISTOR FORMED BY USING THE SAME

(71) Applicant: National Yang Ming Chiao Tung University, Hsinchu City (TW)

(72) Inventors: Bing-Yue TSUI, Hsinchu City (TW); Huai-Lin HUANG, Puli Township (TW); Wen-Shu CHEN, Kaohsiung City (TW); An-Ching LI, Taichung City (TW); Chia-Lung HUNG, Hsinchu City (TW); Yi-Kai HSIAO, Hsinchu City (TW)

(73) Assignee: National Yang Ming Chiao Tung University, Hsinchu City (TW)

(21) Appl. No.: 19/251,299

(22) Filed: Jun. 26, 2025

(30) Foreign Application Priority Data
Mar. 24, 2025 (TW) 114110943

(51) Int. Cl. H10D 62/10; H01L 21/3105; H10D 30/01; H10D 30/66; H10D 62/80; H10D 62/83; H10D 62/832; H10D 62/85; H10D 64/27; H10D 64/68

(52) U.S. Cl. CPC H10D 62/102; H10D 30/0297; H10D 30/668; H10D 62/124; H10D 62/8303; H10D 62/8325; H10D 62/8503; H10D 62/875; H10D 64/516; H10D 64/683; H10P 95/00

(57) ABSTRACT

A fabrication process method for increasing an oxide thickness at trench bottom and a trench gate metal-oxide-semiconductor field-effect transistor formed by using the same are provided. A transistor structure involved with a lithography process is employed to define a trench. A pad oxide layer is deposited along the trench and a silicate glass is subsequently formed covering the pad oxide layer on two opposite sidewalls. As such, two silicate glass spacers are formed, retaining a spacing there in between. An annealing process is performed such that the silicate glass flows, filling the spacing at the trench bottom. Therefore, a thick oxide layer is formed at the trench bottom. The present invention is effective in increasing an oxide thickness at the trench bottom, the corner curvature radius of the gate bottom edge, and reducing a parasitic gate-drain capacitance.

### BACKGROUND OF THE INVENTION

This application claims priority for the TW patent application no. 114110943 filed on 24 Mar. 2025, the content of which is incorporated by reference in its entirely.

### FIELD OF THE INVENTION

The present invention relates to process fabrication techniques which are aimed to increase an oxide thickness at trench bottom. More particularly, the present invention is related to a fabrication process method, in which silicate glass is operable to flow from the trench sidewall to the bottom of the trench after high-temperature annealing process, thereby filling the bottom of the trench to form a thick oxide layer. A trench gate metal-oxide-semiconductor field-effect transistor (UMOSFET) formed by using the disclosed fabrication process method is provided at the same time.

### DESCRIPTION OF THE PRIOR ART

As known, a trench gate metal-oxide-semiconductor field-effect transistor (also known as an UMOSFET) is a kind of high-voltage metal-oxide-semiconductor field-effect transistor (HV MOSFET) which has small cell pitch, and thus makes an UMOSFET a semiconductor device with low specific on-resistance (R_{on, sp}). Please refer to FIG. 1, which shows a schematic diagram of a basic structure of a conventional N-type UMOSFET in the prior art. As shown, when a gate voltage is applied to the gate 10 and the gate voltage is sufficient to produce an inversion layer at the interface between the p-type region (illustrated as “P-body” in the figure) 12 and the trench oxide layer 13, that is, the gate voltage is greater than a threshold voltage for the transistor to conduct, under such condition, electrons will flow from the N+ 14 (source region) in the upper place into the channel of the inversion layer, then enter the N− 15 (drift region) and finally reach the N+ 16 (drain region) at its back end. In general, in order to form a complete channel, it is believed that a trench depth of the gate 10 must exceed the p-type region 12 and enter the N− 15 (drift region).

In view of the trending developments of the existing technologies, since silicon carbide (SiC) has a wider bandgap and a higher breakdown field than silicon does, the UMOSFET which is made of silicon carbide, comparatively sustain ten times as large blocking voltage as the UMOSFET which is made of silicon does. Therefore, the silicon carbide UMOSFET device is known as achieving in sustaining grandly high breakdown voltages with low on-state resistance (Rₒₙ) and thin drift layer. However, it draws our attention that, when a large voltage is applied to the drain, the effect of electric field crowding often occurs on both sides of its gate bottom of the transistor due to less radius of curvature on both sides of the gate bottom. As such, it affects the breakdown voltages and lowers the breakdown voltages. In addition, for SiC devices, the wafer usually takes the (0001) crystal plane as its commonly used front side, and the (11-20) crystal plane or (1-100) crystal plane as its trench sidewall. Normally, the electron mobility along the (11-20) crystal plane or along the (1-100) crystal plane will be much higher than the electron mobility along the (0001) crystal plane, so that the transistor can have a lower on-resistance. Nevertheless, it is known that the thermal oxidation rate of the (0001) crystal plane is much lower than that of the (11-20) crystal plane and lower than that of the (1-100) crystal plane. Under such a condition, if the gate oxide layer of the transistor is formed by thermal oxidation, then it is obtained that the thickness at the trench bottom will be thinner than the thickness at its sidewall. Moreover, when taking the electric field crowding and enhancement effect at the corners on both sides of the trench bottom into considerations, then it is apparent that, the transistor will be very likely to fail due to its gate oxide breakdown. So far, there have been related technologies being proposed, which perform to control the chemical vapor deposition (CVD) process parameters so as to make the deposition rate on the sidewall less than the deposition rate on its bottom. By doing so, the bottom oxide layer can be controlled to be thicker than the sidewalls. However, the electric field crowding and enhancement effect at the corners on both sides of the trench bottom still cannot be avoided, so the breakdown voltage of the transistor is still limited by breakdown of its gate oxide layer.

Based on the above-mentioned issues to be solved, another prior art, as indicated in FIG. 2, proposes to use and dispose a P-type region 31 in the N− 30 (drift region), which is configured to be close to the bottom of the gate 32, and thus forms a depletion area by the p-n junction to deplete the trench bottom for reducing the electric field of the gate oxide layer. However, when the transistor is turned on, the depletion area formed by the p-n junction will also be an obstacle to its current flow, causing the junction gate field-effect transistor (JFET) effect, thereby increasing the on-resistance of the device accordingly. Therefore, such method still has unavoidable issues to be solved. And yet, another prior art proposes to use a silicon dioxide to fill the trench first, after the trench is formed by etching. After that, a chemical mechanical polishing (CMP) process is then employed to remove the silicon dioxide, which is located outside the trench. Later, for the remaining silicon dioxide, which is located in the trench, it is feasible to adopt an etching process to etch the silicon dioxide in the trench, and merely leaves silicon dioxide of expected thickness as required. However, such method must be involved with a high-cost CMP process. Moreover, the thickness of the oxide layer at the bottom of the trench is also difficult to control precisely, and thus, cannot be brought into actual mass production stage.

In addition to FIG. 2, FIG. 3 discloses another process diagram for protecting the gate oxide layer at the bottom of the trench. From the structure as shown in FIG. 3, it can be seen that the transistor structure includes a bottom metal layer 151, and then a silicon carbide substrate 153 and a silicon carbide drift region 155 are successively stacked thereon. The structure as disclosed in FIG. 3 includes fabricating protection trenches having a depth the same as or deeper than the channel trench on both sides of the channel trench. After that, a P-type heavily doped region (P+ 157 shown in the figure) is employed to cover the formed protection trench, and since the electric field shielding effect can be generated due to the adjacent P+ regions, the electric field strength at the bottom of the trench is expected to be reduced. However, such methodology still has drawbacks, including the known JFET effect which is most likely to occur between the adjacent P+ regions, thereby increasing the on-resistance. In addition, fabricating protection trenches having deeper depth will also increase the difficulty and complexity of such process method and unfavorable to reducing the cell pitch of the transistor.

In another aspect, please refer to FIG. 4, which discloses one another process diagram for protecting the gate oxide layer at the bottom of the trench. In view of the structure as shown in FIG. 4, it can be seen that in such transistor structure, a P-type heavily doped region (P+ 167 as shown in the figure) having a depth deeper than the trench depth is used to encompass the right half of the trench, and the shielding effect due to the adjacent P-type heavily doped regions is employed to reduce the electric field strength at the left half of the trench bottom. As aforementioned, such methodology process also increases the on-resistance due to the JFET effect between adjacent P+ regions. In addition, only half portion of each trench can be conductive, making the on-resistance of the transistor even greater, which are also shortcomings of FIG. 4.

And yet, another prior art proposes to use ion implantation to make amorphous silicon carbide at the bottom of the trench so as to increase its oxidation rate, and hopefully, to grow a thicker oxide layer by thermal oxidation. However, it is still worth noticing that the oxidation temperature of such method is lower than the temperature required for the recrystallization of the silicon carbide. Therefore, it is very likely that defects will remain in the device structure and affect the performance of the device. As a result, it is believed that these remaining defects may affect the practical application of this method.

And moreover, regarding a trench gate metal-oxide-semiconductor field-effect transistor (the UMOSFET), since it is known that its trench gate bottom overlaps with the drain, forming a parasitic gate-drain capacitance (C_{GD}), also known as the feedback capacitance or the reverse transfer capacitance (Cᵣₛₛ), such parasitic gate-drain capacitance is a key factor to affect the transistor switching speed and switching power consumption. Among the above-mentioned techniques involving with providing depletion area or increasing the oxide layer thickness at the trench bottom for protecting the gate oxide layer, although it can be found to reduce the parasitic gate-drain capacitance, nevertheless, a much lower parasitic gate-drain capacitance is still to be expected for the current UMOSFETs.

Therefore, on account of above, to overcome the above-mentioned problems, it should be obvious that there is indeed an urgent need for the professionals in the field for proposing a new process method to be developed that can effectively solve the above-mentioned problems occurring in the prior design. And by using such process method, the oxide thickness at the trench bottom of an UMOSFET can be effectively increased and the parasitic gate-drain capacitance (C_{GD}) can be reduced at the same time. As a result, by providing the present invention, it is believed that those long-standing shortcomings in the prior arts can be successfully solved. Hereinafter, the detailed specific implementations will be fully described in the following paragraphs.

### SUMMARY OF THE INVENTION

In order to overcome the above-mentioned disadvantages, one major objective in accordance with the present invention is to provide a gate fabrication method, which is applicable to a trench gate metal-oxide-semiconductor field-effect transistor (the UMOSFET). By employing the disclosed gate fabrication method of the present invention, the oxide thickness at the bottom of the trench region can be effectively increased due to the silicate glass flowing toward and filling the bottom of the trench. Meanwhile, the curvature of the trench corner can be reduced at the same time. Given that the same voltage is applied to the power transistor, it is believed that the electric field intensity of the oxide at the trench bottom is reduced, thereby enhancing the breakdown voltages of the device it is applied to.

In addition, another objective of the present invention is to provide a fabrication process method for increasing an oxide thickness at trench bottom and a trench gate metal-oxide-semiconductor field-effect transistor formed by using the same. According to the disclosed technical contents, two spacers made of silicate glass are configured, wherein a spacing is retained there in between the two spacers. After a thermal process is performed, the silicate glass is able to flow toward the spacing and to fill the spacing and the bottom of the trench. Therefore, a thick oxide layer at the bottom of the trench can be formed. By employing the present invention, it is effective to increase the oxide thickness at the bottom of the trench and the radius of curvature of the corner of the bottom of the trench. In addition, a gate-drain capacitance (C_{GD}) can be reduced at the same time.

For achieving the above mentioned objectives, the technical solutions of the present invention are aimed to provide an improved and modified fabrication process method so as to increase an oxide thickness at trench bottom. According to the disclosed process method of the present invention, it comprises a plurality of following steps as provided below:
(a): providing a semiconductor substrate and forming a drift region on the semiconductor substrate.
(b): forming a first heavily doped region in the drift region. Regarding such step, a source ion implantation process may be adopted so as to form the first heavily doped region in the drift region.
(c): later, a second heavily doped region and a third heavily doped region are respectively formed on opposite sides of the first heavily doped region. And a well region is further formed between the first heavily doped region, the second heavily doped region, the third heavily doped region and the drift region.
(d): and then, a hard mask layer is deposited on the first heavily doped region, the second heavily doped region and the third heavily doped region, and a lithography process is then used to form a trench. According to the embodiment of the present invention, the trench extends through the first heavily doped region and the well region, and the bottom of the trench ends in the drift region.

In one embodiment of the present invention, the hard mask layer, for example, can be made of silicon dioxide (SiO₂).
(e): subsequently, removing the hard mask layer and depositing a pad oxide layer, such that the pad oxide layer covers at least two opposite sidewalls and a bottom of the trench.

According to the embodiment of the present invention, a low-pressure chemical vapor deposition (LPCVD) process or a plasma enhanced chemical vapor deposition (PECVD) process can be alternatively adopted to deposit the pad oxide layer. Regarding the formed pad oxide layer, in one applicable embodiment, a thickness of the pad oxide layer covering the two opposite sidewalls of the trench can be, for instance, between 30~200 nanometers. And the thickness of the pad oxide layer covering the bottom of the trench can be, for instance, between 30~300 nanometers.
(f): after the pad oxide layer is deposited, the present invention proceeds to deposit a silicate glass which covers the pad oxide layer on the two opposite sidewalls of the trench, such that two spacers made of the silicate glass can be formed on the two opposite sidewalls of the trench. Also, a spacing is retained between the two spacers.

According to the embodiment of the present invention, specifically, each spacer (the silicate glass) is correspondingly disposed according to one sidewall of the trench, such that the aforementioned spacing can be retained between the two spacers (the silicate glass).

According to the embodiment of the present invention, regarding a thickness of the silicate glass deposited in the step of (f), the thickness of the silicate glass can be, for instance, between 100~300 nanometers. And an anisotropic etching process can be employed to etch the silicate glass so as to form the two spacers having the spacing there in between.

In one embodiment, each of the two spacers is able to have a thickness between 50~250 nanometers, and a height between 0.5~2.0 micrometers, for example.
(g): after that, the present invention proceeds to perform a thermal process such that by adopting the thermal process, the silicate glass (the two spacers) is able to flow toward the spacing and fill the spacing and the bottom of the trench. As a result, a thick oxide layer (also known as a thick bottom oxide, TBOX) can be effectively formed at the bottom of the trench.

According to the technical characteristics of the present invention, in order to provide the silicate glass having a flowing property, the silicate glass adopted by the Application, can be made of borophosphosilicate glass (BPSG), borosilicate glass (BSG), phosphosilicate Glass (PSG), or arsenic silicate glass (ASG). However, the present invention is certainly not limited thereto.

Preferably, according to an optimal embodiment of the present invention, it is feasible that a boron, phosphorus, or arsenic dopant concentration of the silicate glass is between 1%~5%.

In addition, as mentioned in the previous step of (g), the performed thermal process is an annealing process. And a process temperature of the annealing process can be, and not limited to 900° C.~1300° C. Also, a process time of the annealing process can be, and not limited to 5~120 minutes. In general, various modifications and variations to the present invention can be made by people who are skilled in the art, without departing from the scope or spirits of the invention. And yet, the present invention covers these modifications and/or variations provided that, they fall within the scope of the invention and its equivalent. The present invention is certainly not limited to the disclosed parameters and conditions as illustrated above.

As a result, by employing the present invention, it is believed that the thick oxide layer formed by using the present invention, is able to have a side thickness on both sides and a central thickness at a center of the thick oxide layer, and the side thickness is greater than the central thickness, so that a surface of the thick oxide layer is in an upward curved shape. Based on such technical characteristics, the present invention achieves effectively in increasing the thickness of the oxide layer at the bottom of the trench, reducing the electric field strength of the oxide layer at the bottom of the trench, and increasing the curvature radius of the trench bottom, thereby enhancing the breakdown voltage of the transistor.

As a result, it is believed that the parasitic gate-drain capacitance (C_{GD}) can be effectively reduced as well. Apart from the above, the present invention is also characterized by simple process method and under easy control. As compared to the prior arts, it comprises both unique innovation and practical application.

And furthermore, in another aspect, the present invention additionally provides a trench gate metal-oxide-semiconductor field-effect transistor formed by using the fabrication process method for increasing the oxide thickness at trench bottom as mentioned above. The proposed trench gate metal-oxide-semiconductor field-effect transistor (also known as an UMOSFET) mainly comprises the above-mentioned semiconductor substrate, the drift region formed on the semiconductor substrate, the well region formed on the drift region, the first heavily doped region, the second heavily doped region, the third heavily doped region, the pad oxide layer, and the proposed thick oxide layer.

According to the embodiment of the present invention, the second heavily doped region and the third heavily doped region are respectively formed on the opposite sides of the first heavily doped region, and the first heavily doped region, the second heavily doped region and the third heavily doped region are disposed on the well region. The trench formed by using the lithography is used to separate the first heavily doped region and to separate the well region.

The pad oxide layer is configured, as covering at least the two opposite sidewalls and the bottom of the trench, and the thick oxide layer is formed on the pad oxide layer, wherein the thick oxide layer is formed at the bottom of the trench and filling the bottom of the trench. According to the embodiment of the present invention, the thick oxide layer is made of the silicate glass, and the thick oxide layer has a side thickness on both sides and a central thickness at a center of the thick oxide layer. The side thickness is greater than the central thickness, so that a surface of the thick oxide layer is in an upward curved shape.

In one preferred embodiment of the present invention, the material of the semiconductor substrate used in the present invention may be, for example, a silicon carbide (SiC) substrate. However, the fabrication process method and the UMOSFET formed by using the fabrication process method therein the present invention are not limited to the disclosed silicon carbide material. Based on the same design manners, it is believed that the technical solutions disclosed in the present invention can also be widely applied to other semiconductor materials. For example, the material of the semiconductor substrate can also be made of silicon (Si), gallium oxide (Ga₂O₃), aluminum nitride (AlN), diamond, and so on. Besides, the types of transistors that the present invention can be applied to are not limited to transistors with N-type channels. It may also be applied to transistors with P-type channels. In other words, according to the fabrication process method disclosed in the present invention and the UMOSFET formed thereof, the semiconductor substrate, the drift region, and the first heavily doped region used, have a first semiconductor conductivity type. And the second heavily doped region, the third heavily doped region and the well region have a second semiconductor conductivity type. The first semiconductor conductivity type and the second semiconductor conductivity type are opposite conductivity types.

And furthermore, in view of the filed application of the present invention, it is believed that its application field is not limited to the above-mentioned UMOSFETs. According to a plurality of variant embodiments of the present invention, it can alternatively be further widely applied to any power device which includes the UMOSFET structure, for example, an Insulated Gate Bipolar Transistor (IGBT). As a matter of fact, it is apparent that the present invention shows superior industrial applicability and technical compatibility.

Based on the above, it is believed that the present invention proposes a fabrication process method for increasing the oxide thickness at trench bottom and its UMOSFET structure formed thereof. According to the disclosed process techniques, a pad oxide layer is deposited on both sidewalls and bottom of the trench and a silicate glass is subsequently formed covering the pad oxide layer on the two opposite sidewalls. As such, two silicate glass spacers are formed, retaining a spacing there in between. After that, a thermal process (for instance, an annealing process) is performed such that the silicate glass flows, filling the spacing at the trench bottom. Therefore, a thick oxide layer is formed at the trench bottom.

As a result, after the thick oxide layer is effectively formed, a wet etching process can be alternatively adopted by people skilled in the technical arts to remove the silicate glass or the silicon dioxide remaining on the trench sidewalls. And after that, the conventional processes of the current UMOSFETs can be employed, including fabricating the gate oxide layer, depositing and etching back a poly-silicon gate, forming the inter layer dielectric (ILD), forming the contact window by lithography, depositing and etching metal to define metal patterns, forming passivation layer, polishing and thinning wafer back, and performing metallization process, thereby completing the manufacturing of the UMOSFETs. Since these above-mentioned process details have been acknowledged in the technical backgrounds, the Applicants of the present invention omit the redundant descriptions.

According to one embodiment of the present invention, the depth of the trench can be, for example, between 1~2 micrometers, and a width of the trench can be, for example, between 0.5~2 micrometers.

As a result, on account of the technical contents as disclosed above, it is believed that by employing the disclosed technical process method, the present invention achieves in reducing the overlap area of the gate and drain regions effectively, so as to decrease the parasitic gate-drain capacitance (C_{GD}).

Also, regarding to another aspect of the advantages, the present invention also achieves in increasing the oxide layer thickness at the trench bottom. Therefore, the trench corner curvature can be effectively reduced, whereby breakdown voltages and reliability of the power device when adopting the present invention can be significantly improved.

It is worth emphasizing that, the embodiments disclosed in the present invention are merely described as taking silicon carbide as an illustrative exemplary example. The purpose is to enable those skilled in the art to fully understand the technical spirits of the present invention, but not intend to limit the application of the present invention. In other words, the process method disclosed in the present invention can be applied not only to silicon carbide substrates, but also to various semiconductor materials. The process method provided by the present invention can also be further applied to various semiconductor materials, and not limited to silicon carbide substrates.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 shows a schematic structural diagram of a basic structure of a conventional N-type UMOSFET in the prior art.

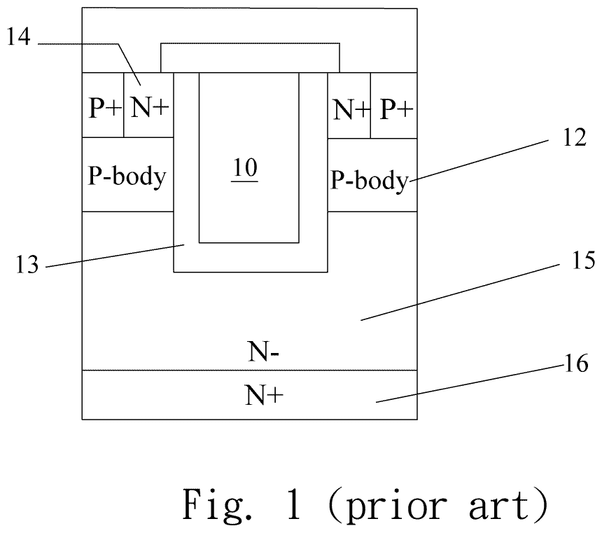

FIG. 2 shows a schematic structural diagram of disposing a P-type region in the bottom of the gate of an UMOSFET in the prior art.

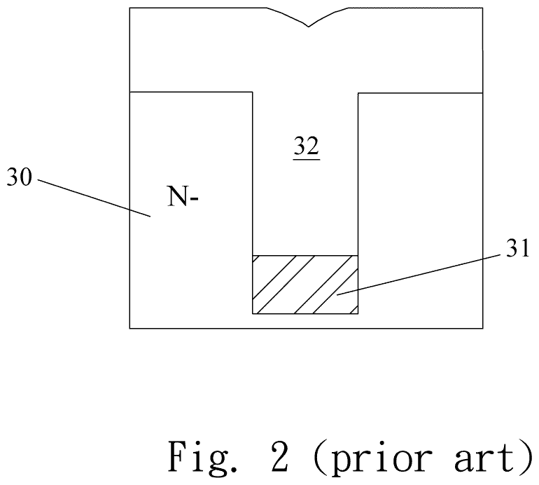

FIG. 3 shows a schematic structural diagram of disposing a P-type heavily doped region to protect the gate oxide layer at the bottom of the trench of an UMOSFET in the prior art.

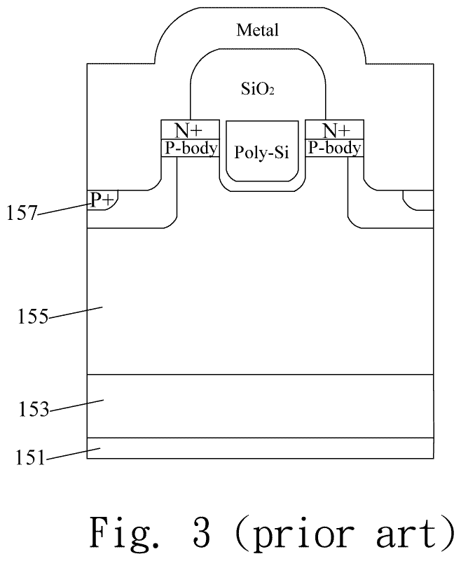

FIG. 4 shows one another schematic structural diagram of disposing a P-type heavily doped region to protect the gate oxide layer at the bottom of the trench of an UMOSFET in the prior art.

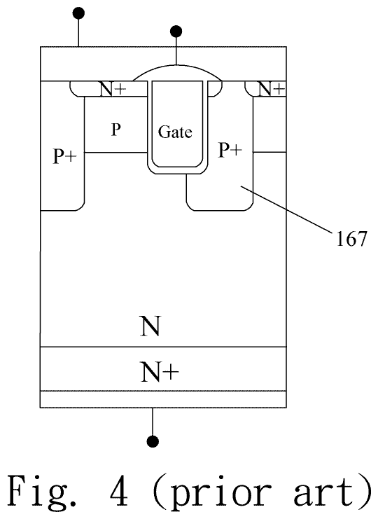

FIG. 5 shows a flow chart illustrating the steps of the fabrication process method for increasing the oxide thickness at trench bottom in accordance with one embodiment of the present invention.

FIG. 6 shows a schematic structural diagram of forming an N-type drift region on an N-type semiconductor substrate in accordance with one embodiment of the present invention.

FIG. 7 shows a schematic structural diagram from FIG. 6 after the source ion implantation process is performed.

FIG. 8 shows a schematic structural diagram from FIG. 7, in which a P-well region and P-type heavily doped regions are further formed therein.

FIG. 9 shows a schematic structural diagram from FIG. 8, in which a silicon dioxide hard mask layer is further deposited.

FIG. 10 shows a schematic structural diagram from FIG. 9 after a lithography process is further employed to define a trench region.

FIG. 11 shows a schematic structural diagram from FIG. 10 after the hard mask layer is removed and a pad oxide layer is deposited.

FIG. 12 shows a schematic structural diagram from FIG. 11, in which a silicate glass is deposited so as to form two spacers according to the embodiment of the present invention.

FIG. 13 shows a schematic structural diagram from FIG. 12, in which a thermal process is performed such that the silicate glass flows toward the spacing and fills the spacing and the bottom of the trench to form a thick oxide layer at the bottom of the trench.

### DESCRIPTION OF THE PREFERRED EMBODIMENTS

It is to be understood that both the foregoing general description and the following detailed description are exemplary and are intended to provide further explanation of the invention as claimed.

Reference will now be made in detail to the preferred embodiments of the present invention, examples of which are illustrated in the accompanying drawings. Wherever possible, the same reference numbers are used in the drawings and the description to refer to the same or like parts.

The embodiments described below are illustrated to demonstrate the technical contents and characteristics of the present invention and to enable the persons skilled in the art to understand, make, and use the present invention. However, it shall be noticed that, it is not intended to limit the scope of the present invention. Therefore, any equivalent modification or variation according to the spirit of the present invention is to be also included within the scope of the present invention.

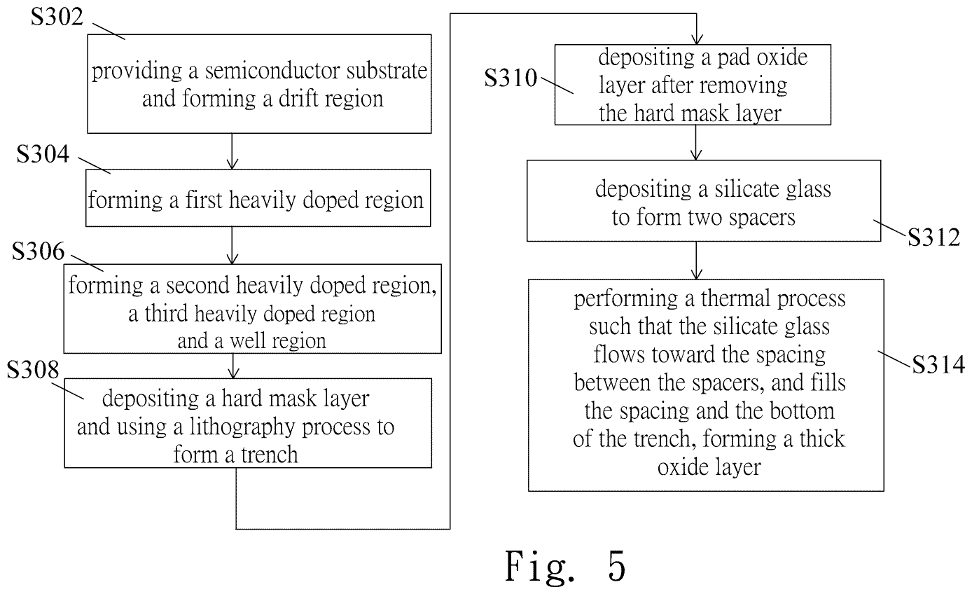

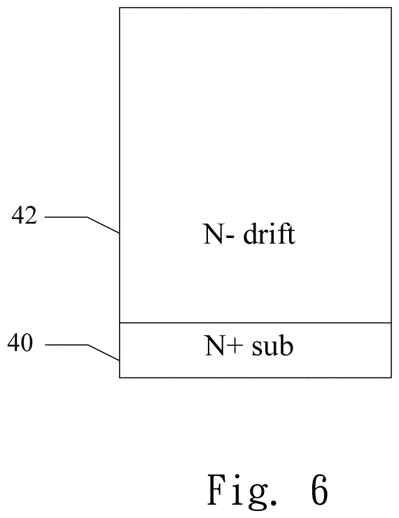

Please refer to FIG. 5, which shows a flow chart illustrating the proposed steps of a fabrication process method for increasing an oxide thickness at trench bottom in accordance with one embodiment of the present invention. The disclosed fabrication method includes the plurality of steps as: the steps of S302, S304, S306, S308, S310, S312 and S314. By adopting the proposed fabrication method for increasing an oxide thickness at trench bottom disclosed in the present invention, it is effective in increasing an oxide thickness at the bottom of the trench gate which is applicable to a UMOSFET structure, meanwhile reducing its corner curvature of the trench. For illustrating the disclosed fabrication process method of the present invention, please refer to FIG. 6 to FIG. 13, which accompanying show schematic cross-sectional views of the structure of an UMOSFET by employing the proposed method disclosed in the present invention.

First, as referring to the step of S302 in FIG. 5, please find FIG. 6, in which a semiconductor substrate 40 is provided and a drift region 42 is formed on the semiconductor substrate 40. In such step, according to one embodiment of the present invention, the semiconductor substrate 40 preferably, can be made of an N-type silicon carbide (SiC). In FIG. 6, it is illustrated as an N-type heavily doped substrate (N+ sub) 40. Afterwards, according to the embodiment of the present invention, an N-type silicon carbide epitaxial layer with a doping concentration of 1×10¹⁶ cm⁻³ and a thickness of 5.5 μm can be grown on the front side of the N+ heavily doped substrate (N+ sub) as the N-drift region (shown as N− drift) 42 by epitaxial growth, so as to form the structure as shown in FIG. 6.

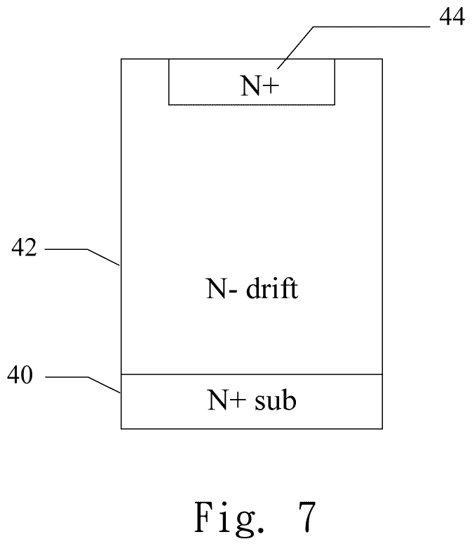

And subsequently, as referring to the step of S304 in FIG. 5, please find FIG. 7, in which a first heavily doped region 44 is formed in the drift region 42. Specifically, after the previous step is complete, the present invention proceeds to perform an RCA cleaning first. Then, silicon dioxide is deposited as a barrier layer, and a lithography process is employed to define an N+ source window. Subsequently, after the source ion implantation, the silicon dioxide barrier layer is removed and the first heavily doped region 44 as shown in FIG. 7, can be formed. In other words, according to the embodiment of the present invention, when regarding forming the first heavily doped region 44 in the drift region 42, it is feasible to use a source ion implantation process for forming the disclosed first heavily doped region 44. According to the embodiment of the present invention, since the N-type silicon carbide material is used as an exemplary example for detailed descriptions, as can be seen in the relevant figures, the first heavily doped region 44 will be illustrated as the N-type heavily doped region (N+).

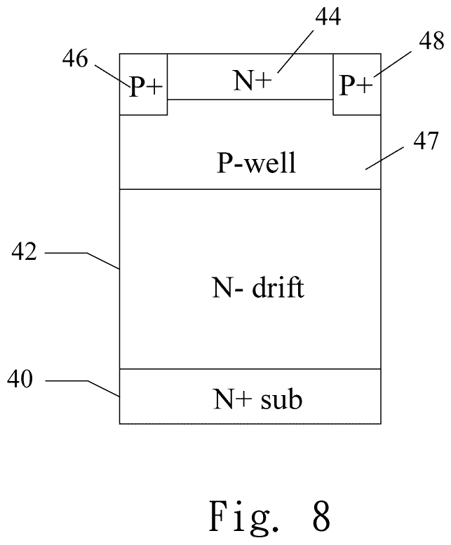

After that, as referring to the step of S306 in FIG. 5, please find FIG. 8, in which the RCA cleaning is performed repeatedly, and definition of the P-type heavily doped region (P+) and ion implantation process are employed for forming a second heavily doped region 46 (shown as “P+” in the figures) and a third heavily doped region 48 (shown as “P+” in the figures) respectively on opposite sides of the first heavily doped region 44 (shown as “N+” in the figures). Later, the silicon dioxide is deposited again as the barrier layer and a lithography process is carried out to define a P-type well region window. A well ion implantation process is then performed, and the silicon dioxide barrier layer is removed such that the well region 47 (shown as “P-well” in the figures) can be formed between the first heavily doped region 44, the second heavily doped region 46, the third heavily doped region 48 and the drift region 42. The structure as illustrated in FIG. 8 is thus obtained.

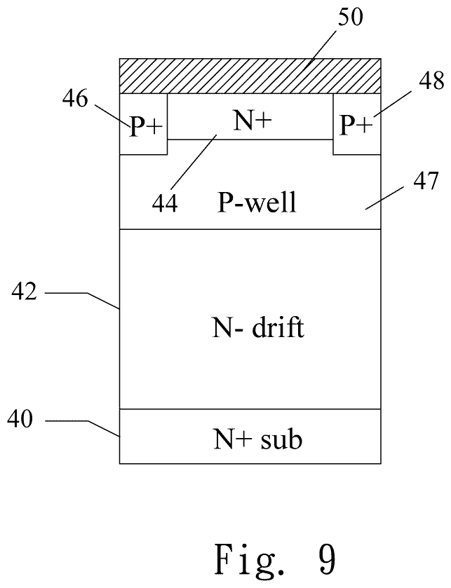

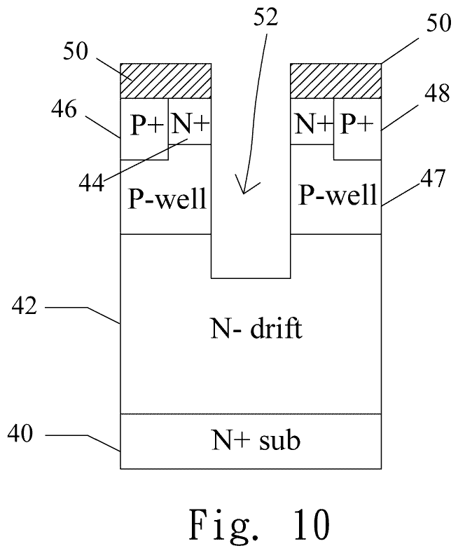

Next, as referring to the step of S308 in FIG. 5, a hard mask layer is subsequently deposited on the above-mentioned first heavily doped region (N+) 44, the above-mentioned second heavily doped region (P+) 46 and the above-mentioned third heavily doped region (P+) 48. And a lithography process is used to form a trench. To be specific, please refer to the structure as shown in FIG. 9, in which the hard mask layer 50 is deposited and shown as a slashed area. According to the embodiment of the present invention, the hard mask layer 50, for instance, can be made of silicon dioxide (SiO₂) as an etch-stop barrier layer for the transistor trench gate region. As can be seen, the hard mask layer 50 is deposited on the first heavily doped region (N+) 44, the second heavily doped region (P+) 46 and the third heavily doped region (P+) 48. And afterwards, please refer to the structure as shown in FIG. 10, the present invention proceeds to adopt a lithography process for defining a trench region of the transistor, such that the trench 52 as illustrated in FIG. 10 can be obtained.

In detailed configurations, according to the embodiment of the present invention, the disclosed trench 52 is designed to have a depth between 1~2 micrometers, and a width of the trench 52 is between 0.5~2 micrometers. In addition, the disclosed trench 52 extends through the first heavily doped region (N+) 44 and the well region (P-well) 47, and the bottom of the trench 52 ends in the drift region (N− drift) 42.

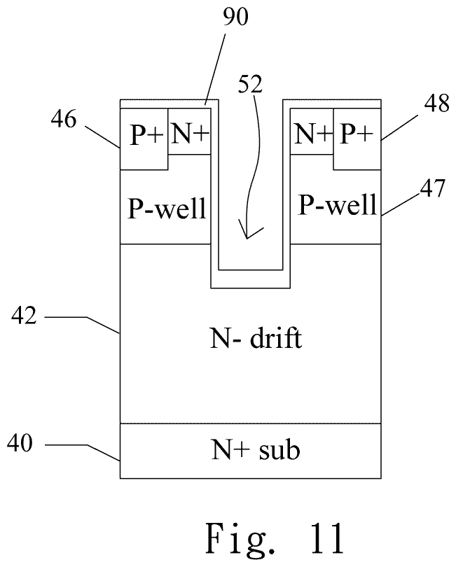

Hereinafter, as referring to the step of S310 in FIG. 5, the present invention proceeds to remove the hard mask layer 50. And after removing the hard mask layer 50, a pad oxide layer is deposited along the trench 52, such that the pad oxide layer covers two opposite sidewalls and a bottom of the trench 52. As illustrated in FIG. 11 of the present invention, it can be seen that the coverage area of the pad oxide layer 90 includes at least two opposite sidewalls and a bottom of the trench 52. Practically, according to the embodiment of the present invention, a low-pressure chemical vapor deposition (LPCVD) process or a plasma enhanced chemical vapor deposition (PECVD) process can be alternatively adopted in order to deposit the pad oxide layer 90. Regarding a practical application, according to one embodiment of the present invention, when the pad oxide layer 90 is formed by using a low-pressure CVD (LPCVD) process, then a bottom thickness of the pad oxide layer 90 will approximately equal to its sidewall thickness. However, the present invention is not limited thereto. For example, in one embodiment, a thickness of the pad oxide layer 90 covering the bottom of the trench can be, for instance, between 30~300 nanometers, preferably, 100 nanometers. And the thickness of the pad oxide layer 90 covering the two opposite sidewalls of the trench 52 can be between 30~200 nanometers.

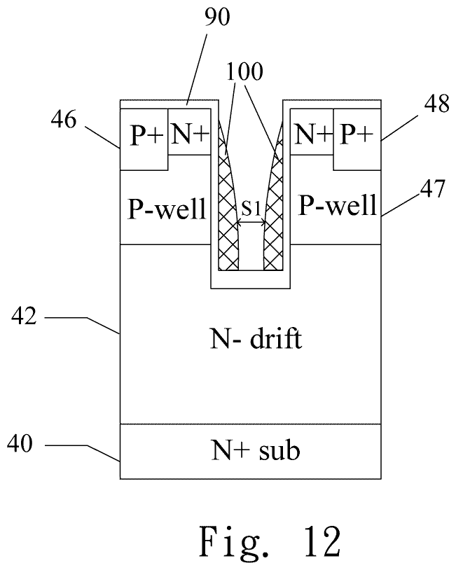

As a result, after the above-mentioned pad oxide layer 90 is deposited, the step of S312 in FIG. 5 can thus be carried out: depositing a silicate glass. According to the embodiment of the present invention, the silicate glass is configured as covering the pad oxide layer 90 on the two opposite sidewalls of the trench 52, such that the two spacers 100 (shown in FIG. 12) are formed. In addition, it can be seen that a spacing S1 is retained between the two spacers 100. To be specific, please refer to FIG. 12, each spacer (made of silicate glass) 100 is disposed corresponding to each sidewall of the trench 52, and the two spacers 100 are commonly disposed on the pad oxide layer 90 on the bottom of the trench 52. It should be noted that, the spacing S1 should be retained and maintained between the two spacers 100 according to the present invention.

In a practical application, when regarding forming the spacers 100 in the step of S312, the present invention is able to adopt a low-pressure chemical vapor deposition (LPCVD) process to deposit the silicate glass first. And after that, an anisotropic etching process can be performed to etch the silicate glass so as to form the proposed two spacers 100 having the spacing S1 there in between. In general, the above-mentioned anisotropic etching process can be optional and alternatively adopted by people skilled in the arts. Generally, a thickness of the silicate glass to be deposited can be, for instance, between 100~300 nanometers. Therefore, after the anisotropic etching process is carried out to etch the silicate glass and form the spacers 100, each spacer 100 has a thickness between 50~250 nanometers and a height between 0.5~2.0 micrometers can be effectively formed.

According to the embodiment of the present invention, the material of the silicate glass, can be and not limited to borophosphosilicate glass (BPSG), borosilicate glass (BSG), phosphosilicate Glass (PSG), or arsenic silicate glass (ASG). To be more specific, a boron, phosphorus, or arsenic dopant concentration of the silicate glass can be between 1%~5%. By such arrangements, it is believed that the spacer 100 made of the silicate glass can be flowable in the following process step.

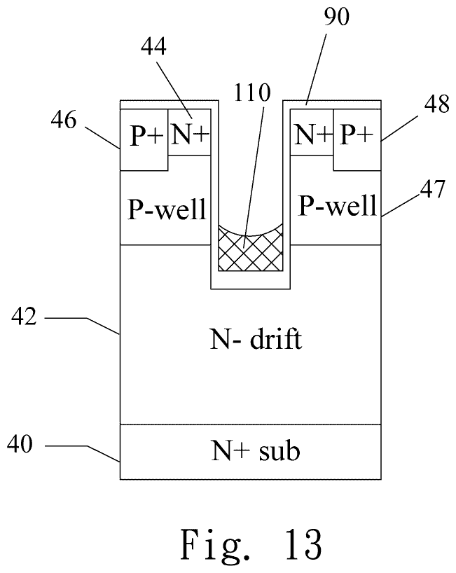

As a result, based on such structure as obtained in FIG. 12, as referring to the step of S314 in FIG. 5, the present invention is able to proceed to perform a thermal process such that the silicate glass flows toward the spacing S1 and fills the spacing S1 and the bottom of the trench 52. As a result, it can be seen that a thick oxide layer 110 is effectively formed at the bottom of the trench, as illustrated in FIG. 13 of the preset invention.

According to the embodiment of the present invention, the aforementioned thermal process can be, for instance, an annealing process, wherein a process temperature of the annealing process is between 900° C.~1300° C. and a process time of the annealing process is between 5~120 minutes. It can be understood that when performing such annealing process, since the spacer 100 (silicate glass) flows from the sidewall of the trench to the bottom of the trench, the formed thick oxide layer 110 is characterized by having a side thickness greater than its central thickness. Please refer to FIG. 13, it can be seen that a surface of the thick oxide layer 110 is in an upward curved shape. According to the embodiment of the present invention, it can be obtained that, the formed thick oxide layer 110 has a side thickness on both sides and a central thickness at a center of the thick oxide layer 110, and the side thickness is greater than the central thickness, so that a surface of the thick oxide layer 110 is in an upward curved shape as shown in FIG. 13.

In general, the thickness of the formed thick oxide layer 110, can be controlled and determined according to various conditions of performing the foregoing annealing process, including: process temperature, process time, and so on. Certain process flexibility is allowed and practical. It is worth emphasizing that, the present invention is definitely not limited to the above-mentioned thickness, dimensions or process parameters, including process temperature, process time, and other process conditions, etc. which were disclosed in the previously described embodiments. For people who are skilled in the art and with ordinary knowledge in the field, modifications without departing from the spirit of the present invention are permitted. However, within the scope of its equality, such modifications should still fall into the scope and claims of the present invention. For instance, according to one feasible embodiment of the present invention, when the width of the trench is 1 micrometer, and a 50 nanometers silicon dioxide is provided on the sidewall of the trench by adopting LPCVD, a BPSG spacer having 100 nanometers of thickness and 1 micrometer of height is able to flow and fill in the bottom of the trench to form a 222 nanometers BPSG at the trench bottom. As a result, a thick oxide layer of 322 nanometers (including the original 100 nanometers silicon dioxide by LPCVD) can be effectively obtained. However, the present invention is certainly not limited thereto. According to other feasible embodiments of the present invention, various height and thickness of the BPSG spacer can be alternatively configured in order to obtain a variety of thickness of the formed thick oxide layer when necessary.

As a result, it is obvious that the present invention proposes a fabrication process method for increasing the oxide thickness at trench bottom and its trench gate metal-oxide-semiconductor field-effect transistor (UMOSFET) structure formed thereof. According to the disclosed process techniques, a silicate glass is provided to form as two spacers on the two opposite sidewalls of the trench. After that, an annealing process is performed such that the silicate glass flows, filling the spacing between the two spacers, and fills at the trench bottom. Therefore, a thick oxide layer is formed at the trench bottom. By employing the present invention, it effectively increases the thickness of the oxide layer at the bottom of the trench and reduces the curvature of the trench corner. When applying the technical solution as disclosed in the present invention to any type of power device having a trench gate, it can further improve and optimize the breakdown voltage of the power device. Besides, it is worth noting that in view of the filed application of the present invention, it is believed that its application field is not limited to the above-mentioned UMOSFETs. According to a plurality of variant embodiments of the present invention, it can alternatively be further widely applied to any power device which includes the UMOSFET structure, for example, an Insulated Gate Bipolar Transistor (IGBT). As a matter of fact, it is apparent that the present invention shows superior industrial applicability and technical compatibility.

Apart from the above, according to the process method disclosed in the present invention, its application field is certainly not limited to the N-type silicon carbide substrate but can also be widely applied to a variety of semiconductor substrates, including transistors with an N-type channel or a P-type channel. Among the technical contents, it is believed that the semiconductor substrate, the drift region and the first heavily doped region disclosed in the present invention have a first semiconductor conductivity type. The second heavily doped region, the third heavily doped region and the well region disclosed in the present invention have a second semiconductor conductivity type, and the first semiconductor conductivity type and the second semiconductor conductivity type are opposite conductivity types. In other words, according to one embodiment of the present invention, when the first semiconductor conductivity type is N type, the second semiconductor conductivity type will be P type. And in an alternative embodiment of the present invention, when the first semiconductor conductivity type is P type, then the second semiconductor conductivity type will be N type. The above-mentioned first and second semiconductor conductivity types are not intended to limit the claim scopes of the invention. Moreover, the present invention is also not limited by the above-mentioned process layouts (N-channel or P-channel) as described in the descriptions. In other words, those skilled in the art are able to make equivalent modifications and variations based on the actual product specifications without departing from the spirits of the invention. Nevertheless, such modified embodiments should still fall within the claim scope of the present invention.

As a result, to sum up, the present invention not only discloses a fabrication process method for increasing an oxide thickness at trench bottom, but also discloses a trench gate metal-oxide-semiconductor field-effect transistor (also known as an UMOSFET) formed by using the proposed fabrication process method. The disclosed UMOSFET, as illustrated in FIG. 13 of the present invention, includes the semiconductor substrate (N+ sub) 40, the drift region (N− drift) 42, the well region (P-well) 47, the first heavily doped region (N+) 44, the second heavily doped region (P+) 46, the third heavily doped region (P+) 48, the pad oxide layer 90 and the thick oxide layer 110. According to the embodiment of the present invention, the pad oxide layer 90 covers the two opposite sidewalls and the bottom of the trench and the thick oxide layer 110 is formed on the pad oxide layer 90. In addition, the thick oxide layer 110 is formed at the bottom of the trench and filling the bottom of the trench. And the thick oxide layer 110 is made of the silicate glass, the thick oxide layer 110 has a side thickness on both sides and a central thickness at a center of the thick oxide layer 110, wherein the side thickness is greater than the central thickness, so that a surface of the thick oxide layer 110 is in an upward curved shape.

As a result, after the UMOSFET structure is obtained by employing the present invention, a plurality of post end processes afterwards can be alternatively adopted by those having ordinary knowledge backgrounds and skilled in the art. For instance: depositing a dielectric layer on the gate metal layer (dielectric deposition), defining and etching at least one metal contact window, metal deposition, metal etching, and so on. Since these post end processes are basically the same as they are performed in the current processes of the UMOSFETs, the present invention is therefore not repeated here in after and not intended to provide detailed descriptions. The main technical spirits of the present invention are aimed to form a thick oxide layer at the bottom of the trench of an UMOSFET. And since the trench is merely partially filled with the polysilicon gate, a parasitic gate-drain capacitance C_{GD} can be significantly reduced at the same time. As such, it is believed that the present invention achieves in increasing the oxide thickness at the bottom of the trench, reducing the trench corner curvature, and suppressing the conventional electrical field enhancement effect at the trench corner. Meanwhile, the conventional gate-drain capacitance C_{GD} can be effectively reduced according to certain overlap percentage.

As a result, to sum above, it can be expected that by employing the disclosed technical contents and features of the present invention, the proposed fabrication process method and formed transistor structure are beneficial to 1. increasing the oxide thickness at the bottom of the trench, 2. reducing trench corner curvature, and 3. decreasing the conventional parasitic gate-drain capacitance C_{GD}.

Based on such technical contents, by employing the process method as disclosed in the present invention, not only the thickness of the oxide layer at the bottom of the gate can be increased, but at the same time, the conventional electric field enhancement and crowding effect at the corner of the trench and various problems derived therefrom are eliminated. Also in a further aspect, when applying the disclosed process method and its transistor structure formed thereof the present invention, it is believed that in addition to the silicon carbide substrates, a plurality of various substrates made of other semiconductor materials, such as silicon (Si), gallium oxide (Ga₂O₃), aluminum nitride (AlN), and diamond, etc. are applicable as well. Therefore, as a matter of fact, the Applicants assert that the present invention is instinct, effective and highly competitive for the incoming technologies, industries and researches developed in the future. And since the technical features, means and effects achieved by the present invention are significantly different from the current solutions and can not be accomplished easily by those who are familiar with the industry, it is thus believed that the present invention is indeed characterized by patentability and shall be patentable soon in a near future.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A fabrication process method for increasing an oxide thickness at trench bottom, comprising:
providing a semiconductor substrate and forming a drift region on the semiconductor substrate;
forming a first heavily doped region in the drift region;
forming a second heavily doped region and a third heavily doped region respectively on opposite sides of the first heavily doped region, and providing a well region between the first heavily doped region, the second heavily doped region, the third heavily doped region and the drift region;
depositing a hard mask layer on the first heavily doped region, the second heavily doped region and the third heavily doped region, and using a lithography process to form a trench;
depositing a pad oxide layer after removing the hard mask layer, wherein the pad oxide layer covers two opposite sidewalls and a bottom of the trench;
depositing a silicate glass, wherein the silicate glass covers the pad oxide layer on the two opposite sidewalls of the trench to form two spacers, and a spacing is retained between the two spacers; and
performing a thermal process such that the silicate glass flows toward the spacing and fills the spacing and the bottom of the trench, forming a thick oxide layer at the bottom of the trench.

2. The fabrication process method for increasing the oxide thickness at trench bottom according to claim 1, wherein a depth of the trench is between 1~2 micrometers, and a width of the trench is between 0.5~2 micrometers.

3. The fabrication process method for increasing the oxide thickness at trench bottom according to claim 1, wherein the pad oxide layer is made of silicon dioxide (SiO₂).

4. The fabrication process method for increasing the oxide thickness at trench bottom according to claim 1, further comprising using a low-pressure chemical vapor deposition (LPCVD) process or a plasma enhanced chemical vapor deposition (PECVD) process to deposit the pad oxide layer.

5. The fabrication process method for increasing the oxide thickness at trench bottom according to claim 1, wherein a thickness of the pad oxide layer covering the two opposite sidewalls of the trench is between 30~200 nanometers.

6. The fabrication process method for increasing the oxide thickness at trench bottom according to claim 1, wherein a thickness of the pad oxide layer covering the bottom of the trench is between 30~300 nanometers.

7. The fabrication process method for increasing the oxide thickness at trench bottom according to claim 1, wherein a thickness of the silicate glass is between 100~300 nanometers.

8. The fabrication process method for increasing the oxide thickness at trench bottom according to claim 1, wherein in the step of forming the two spacers further comprises:
using an anisotropic etching process to etch the silicate glass so as to form the two spacers having the spacing there in between.

9. The fabrication process method for increasing the oxide thickness at trench bottom according to claim 8, wherein each of the two spacers has a thickness between 50~250 nanometers.

10. The fabrication process method for increasing the oxide thickness at trench bottom according to claim 8, wherein each of the two spacers has a height between 0.5~2.0 micrometers.

11. The fabrication process method for increasing the oxide thickness at trench bottom according to claim 1, wherein the silicate glass is made of borophosphosilicate glass (BPSG), borosilicate glass (BSG), phosphosilicate Glass (PSG), or arsenic silicate glass (ASG).

12. The fabrication process method for increasing the oxide thickness at trench bottom according to claim 11, wherein a boron, phosphorus, or arsenic dopant concentration of the silicate glass is between 1%~5%.

13. The fabrication process method for increasing the oxide thickness at trench bottom according to claim 1, wherein the thermal process is an annealing process.

14. The fabrication process method for increasing the oxide thickness at trench bottom according to claim 13, wherein a process temperature of the annealing process is between 900° C.~1300° C.

15. The fabrication process method for increasing the oxide thickness at trench bottom according to claim 13, wherein a process time of the annealing process is between 5~120 minutes.

16. The fabrication process method for increasing the oxide thickness at trench bottom according to claim 1, wherein the thick oxide layer has a side thickness on both sides and a central thickness at a center of the thick oxide layer, and wherein the side thickness is greater than the central thickness, so that a surface of the thick oxide layer is in an upward curved shape.

17. The fabrication process method for increasing the oxide thickness at trench bottom according to claim 1, wherein the semiconductor substrate, the drift region and the first heavily doped region have a first semiconductor conductivity type, the second heavily doped region, the third heavily doped region and the well region have a second semiconductor conductivity type, and the first semiconductor conductivity type and the second semiconductor conductivity type are opposite conductivity types.

18. The fabrication process method for increasing the oxide thickness at trench bottom according to claim 1, wherein the semiconductor substrate is made of silicon (Si), silicon carbide (SiC), gallium oxide (Ga₂O₃), aluminum nitride (AlN), or diamond.

19. The fabrication process method for increasing the oxide thickness at trench bottom according to claim 1, further comprising using a source ion implantation process to form the first heavily doped region in the drift region.

20. The fabrication process method for increasing the oxide thickness at trench bottom according to claim 1, wherein the hard mask layer is made of silicon dioxide (SiO₂).

21. The fabrication process method for increasing the oxide thickness at trench bottom according to claim 1, wherein the trench extends through the first heavily doped region and the well region, and the bottom of the trench ends in the drift region.

22. A trench gate metal-oxide-semiconductor field-effect transistor formed by using the fabrication process method for increasing the oxide thickness at trench bottom according to claim 1, comprising:
the semiconductor substrate;
the drift region formed on the semiconductor substrate;
the well region formed on the drift region;
the first heavily doped region, the second heavily doped region and the third heavily doped region formed on the well region, wherein the second heavily doped region and the third heavily doped region are respectively formed on the opposite sides of the first heavily doped region, the trench formed by using the lithography is used to separate the first heavily doped region and separate the well region;
the pad oxide layer, covering the two opposite sidewalls and the bottom of the trench; and
the thick oxide layer, formed on the pad oxide layer, wherein the thick oxide layer is formed at the bottom of the trench and filling the bottom of the trench, and wherein the thick oxide layer is made of the silicate glass, the thick oxide layer has a side thickness on both sides and a central thickness at a center of the thick oxide layer, and wherein the side thickness is greater than the central thickness, so that a surface of the thick oxide layer is in an upward curved shape.

23. The trench gate metal-oxide-semiconductor field-effect transistor formed by using the fabrication process method for increasing the oxide thickness at trench bottom according to claim 22, wherein the silicate glass is made of borophosphosilicate glass (BPSG), borosilicate glass (BSG), phosphosilicate Glass (PSG), or arsenic silicate glass (ASG).

24. The trench gate metal-oxide-semiconductor field-effect transistor formed by using the fabrication process method for increasing the oxide thickness at trench bottom according to claim 23, wherein a boron, phosphorus, or arsenic dopant concentration of the silicate glass is between 1%~5%.

25. The trench gate metal-oxide-semiconductor field-effect transistor formed by using the fabrication process method for increasing the oxide thickness at trench bottom according to claim 22, wherein a thickness of the silicate glass is between 100~300 nanometers.

26. The trench gate metal-oxide-semiconductor field-effect transistor formed by using the fabrication process method for increasing the oxide thickness at trench bottom according to claim 22, wherein the semiconductor substrate is made of silicon (Si), silicon carbide (SiC), gallium oxide (Ga₂O₃), aluminum nitride (AlN), or diamond.

27. The trench gate metal-oxide-semiconductor field-effect transistor formed by using the fabrication process method for increasing the oxide thickness at trench bottom according to claim 22, wherein the semiconductor substrate, the drift region and the first heavily doped region have a first semiconductor conductivity type, the second heavily doped region, the third heavily doped region and the well region have a second semiconductor conductivity type, and the first semiconductor conductivity type and the second semiconductor conductivity type are opposite conductivity types.

28. The trench gate metal-oxide-semiconductor field-effect transistor formed by using the fabrication process method for increasing the oxide thickness at trench bottom according to claim 22, wherein the pad oxide layer is made of silicon dioxide (SiO₂).

29. The trench gate metal-oxide-semiconductor field-effect transistor formed by using the fabrication process method for increasing the oxide thickness at trench bottom according to claim 22, wherein a depth of the trench is between 1~2 micrometers, and a width of the trench is between 0.5~2 micrometers.

30. The trench gate metal-oxide-semiconductor field-effect transistor formed by using the fabrication process method for increasing the oxide thickness at trench bottom according to claim 22, wherein the thermal process is an annealing process, a process temperature of the annealing process is between 900° C.~1300° C., and a process time of the annealing process is between 5~120 minutes.
